(19) United States
(12) Patent Application Publication
(10) Pub. No.: US 2013/0092837 A1
(43) Pub. Date: Apr. 18, 2013

(54) PATTERN INSPECTION DEVICE AND PATTERN INSPECTION METHOD

(71) Applicant: Hiroshi Yamashita, Shinjuku-ku (JP)

(72) Inventor: Hiroshi Yamashita, Shinjuku-ku (JP)

(73) Assignee: HOYA CORPORATION, Shinjuku-ku, Tokyo (JP)

(21) Appl. No.: 13/640,834

(22) PCT Filed: Apr. 13, 2011
(86) PCT No.: PCT/JP2011/059178

§ 371 Date: Dec. 21, 2012

(30) Foreign Application Priority Data
Apr. 13, 2010 (JP) 2010-092298

(51) Int. Cl. H01J 37/26

(52) U.S. Cl. CPC H01J 37/26
USPC 250/307; 250/310

(57) ABSTRACT

Disclosed is a pattern inspection device for inspecting a bit pattern of a disk medium having a plurality of tracks which are concentrically formed on the disk medium, the bit pattern on each track being spaced for each bit in radial and circumferential directions, the pattern inspection device including: a rotating stage on which the disk medium is placed; an irradiating optical system for radiating an electron beam onto the disk medium that rotates together with the rotating stage; and an electron detector for detecting electrons generated from the disk medium on the rotating stage by the irradiation of the electron beam of the irradiating optical system, wherein a spot diameter of the electron beam of the irradiating optical system is set not less than a diameter of the bit pattern.

### TECHNICAL FIELD

The present invention relates to a pattern inspection device and a pattern inspection method that are applied when inspecting patterns formed on a disk medium.

### BACKGROUND ART

As one of disk media used for magnetic recording and reproducing apparatuses, such as hard disk drive units, a disk medium that is called a “bit patterned medium” has been known. A plurality of recording tracks are concentrically formed on this kind of disk medium. Patterns constituting each track are spaced for each bit in the radial and circumferential directions of the disk medium. In this specification, a pattern that is spaced for each bit, as stated above, is called a “bit pattern”.

Recently, an “imprint technique” has been utilized as a technique for forming the patterns on a disk medium. In the imprint technique, concavo-convex patterns are formed on a base disk medium called a stamper, and the concave and convex of the concavo-convex patterns are transferred from the stamper to another disk medium to form the inverted concave and convex of the concavo-convex patterns. In this case, the concavo-convex patterns are generally formed on a base disk medium by means of a photolithographic technique.

In the photolithographic technique, resist patterns are formed on a substrate which is a base (material) of a disk medium, by sequentially conducting the “formation of resist film”, “exposure of the resist film” and “development of the resist film”. Of those procedures, an electron-beam lithography system is used for the exposure of the resist film. The electron-beam lithography system is an apparatus for exposing the resist film by irradiating the resist film formed on the substrate with an electron beam.

Some electron-beam lithography systems are equipped with a rotating stage which rotates a substrate with a resist film in the circumferential direction. In this type of electron-beam lithography system, patterns are drawn by irradiating the resist film on the substrate with the electron beam while rotating the substrate by driving the rotating stage.

Furthermore, after the patterns have been drawn by irradiating the resist film with the electron beam as stated above, the resist film that has been exposed in the above pattern drawing process is developed, thereby forming the resist patterns on the substrate. Moreover, by etching the substrate using the resist patterns as a mask, a disk medium (substrate) on which the above bit patterns have been formed is obtained.

The bit patterns thus formed in a ring on a disk medium constitute one track. Furthermore, the bit patterns depend on the drawing data used for the pattern drawing by means of the electron beam exposure. However, when producing a disk media with patterns, misalignment or dimensional variation could possibly occur in the finally-obtained bit patterns due to various factors during the lithography (exposure and development) process, or before and after the lithography process.

If a disk medium having the bit patterns which are misaligned or varied in size is, for example, used for imprinting as a base, the patterns will be transferred by reflecting the misalignment and variation of size. Therefore, if a disk medium having the bit patterns which are misaligned or varied in size beyond the clearance level is used for the base and imprinting, defective products are produced frequently. To avoid such disadvantages, it is necessary to inspect a disk media whether the misalignment and variation of size of the bit patterns are within an allowable range or not, and to use only the disk media that have been proven to be good by the inspections as the base.

One of known techniques for inspecting the patterns of disk media is a pattern inspection method that uses a scanning electron microscope (SEM, refer to patent literature 1, for example). In this pattern inspection method, the patterns constituting tracks of a disk medium are irradiated with an electron beam, and secondary electrons generated from the disk medium are detected by a secondary electron detector. Furthermore, the detected electrons are converted into electrical signals and amplified, and then a two-dimensional scan image (hereafter referred to as a “secondary electron image”) is obtained from the amplified electrical signals.

### CITATION LIST

### Patent Literature

Patent literature 1: Japanese Unexamined Patent Application Publication No. 2008-299912 (paragraphs 0006, 0008, FIG. 5)

### SUMMARY OF INVENTION

### Technical Problem

However, conventionally, when inspecting the patterns of a disk medium, a secondary electron image is created based on the result detected by the secondary electron detector, and a shape and a location of each of the patterns are obtained from the secondary electron image. Thus, a series of signal processing related to the pattern inspection are troublesome.

An objective of the present invention is to provide a technique for inspecting the patterns of a disk media more easily than in the case where the shape and location of the patterns are obtained from secondary electron images detected by use of a scanning electron microscope.

### Solution to Problem

A first aspect in accordance with the present invention is a pattern inspection device for inspecting a bit pattern of a disk medium having a plurality of tracks concentrically formed thereon, the bit pattern of each track being spaced for each bit in the radial and circumferential directions, the pattern inspection device comprising:
a rotating stage on which the disk medium is placed;
an irradiating optical system for irradiating the disk medium rotating along with the rotating stage with an electron beam; and
an electron detector for detecting an electron generated from the disk medium on the rotating stage by the irradiation of the electron beam of the irradiating optical system,
wherein a spot diameter of the electron beam from the irradiating optical system is set to not less than a diameter of the bit pattern.

A second aspect in accordance with the present invention is the pattern inspection device according to the first aspect, further including:
determination means for determining whether the bit pattern is good or not by comparison of a detection signal obtained for each bit as a result of detection by the electron detector with a predetermined reference signal.

A third aspect in accordance with the present invention is the pattern inspection device according to the second aspect, in which the determination means compares the detection signal with the reference signal with respect to a signal intensity profile which is expressed by signal intensity in vertical axis and time in horizontal axis.

A fourth aspect in accordance with the present invention is the pattern inspection device according to the third aspect, in which the determination means determines whether the bit pattern is good or not by comparison of output timing of the detection signal defined in the horizontal axis with output timing of the reference signal.

A fifth aspect in accordance with the present invention is the pattern inspection device according to the third or fourth aspect, in which the determination means determines whether the bit pattern is good or not by comparison of an intensity of the detection signal defined in the vertical axis with the intensity of the reference signal, as well as by comparison of a width of the detection signal defined in the horizontal axis with the width of the reference signal.

A sixth aspect in accordance with the present invention is a pattern inspection method for inspecting a bit pattern of a disk medium having a plurality of tracks concentrically formed thereon, the bit pattern of each track being spaced for each bit in the radial and circumferential directions, the pattern inspection method comprising steps of:

rotating the disk medium;

irradiating the disk medium being rotated with an electron beam;

detecting an electron generated from the disk medium at an irradiating position of the electron beam;

setting a spot diameter of the electron beam larger than the diameter of the bit pattern; and

inspecting a bit pattern of each track.

### Advantageous Effects of the Invention

According to the present invention, it is possible to inspect the patterns of the disk media more easily than in the case where a shape and a location of the patterns are obtained from a secondary electron image detected by use of a scanning electron microscope.

### BRIEF DESCRIPTION OF DRAWINGS

FIG. 1 is a schematic diagram showing a configuration example of a pattern inspection device according to an embodiment of the present invention.

FIG. 2 shows an example of a structure of a disk medium that is a target of a pattern inspection.

FIG. 3 is a plan view showing an example of dimensional relationship between a spot diameter of an electron beam and a bit pattern diameter.

FIG. 4 shows an example of an intensity profile of a detection signal obtained when a portion of a bit pattern is scanned with an electron beam.

FIG. 5 is a schematic diagram for explaining a correlation between a bit pattern and a detection signal (part 1).

FIG. 6 is a schematic diagram for explaining a correlation between a bit pattern and a detection signal (part 2).

FIG. 7 is a schematic diagram for explaining a correlation between a bit pattern and a detection signal (part 3).

### DESCRIPTION OF EMBODIMENTS

Hereafter, embodiments of the present invention will be described in detail with reference to the drawings.

The embodiments of the present invention will be described in the following order:

1. Configuration of pattern inspection device

2. Structure of disk medium

3. Pattern inspection method

4. Effects of the embodiments

5. Modifications

<1. Configuration of Pattern Inspection Device>

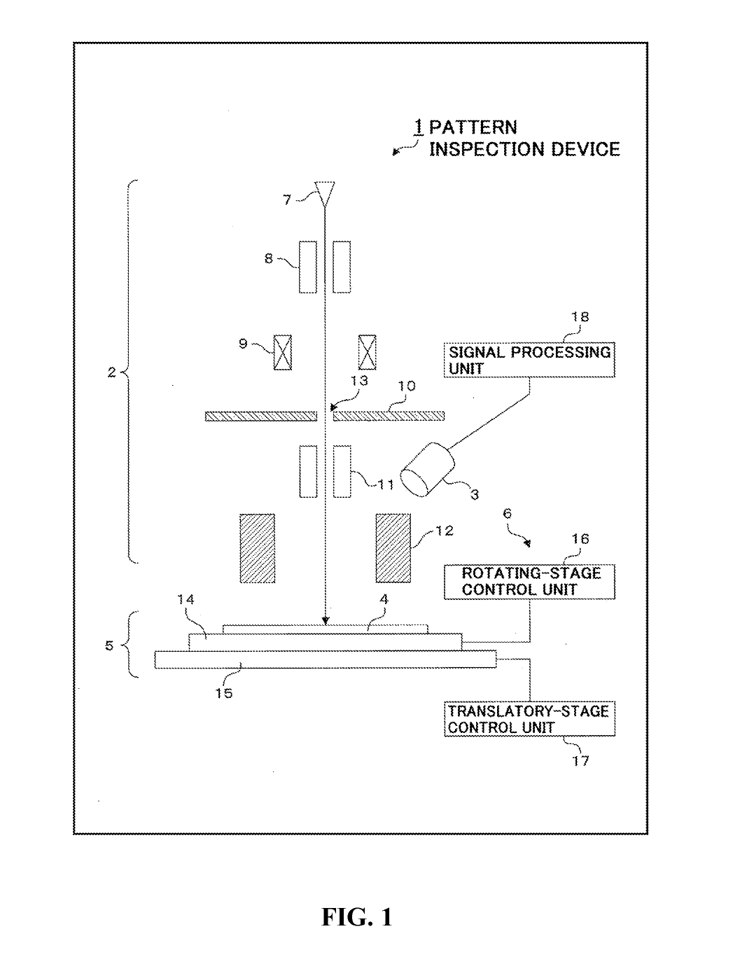

FIG. 1 is a schematic diagram showing a configuration example of a pattern inspection device according to an embodiment of the present invention. The illustrated pattern inspection device 1 mainly includes an irradiating optical system 2 for radiating an electron beam, an electron detector 3 for detecting an electron, a stage mechanism 5 for supporting a disk medium 4 which is a pattern inspection target, and a stage control system 6 for controlling the drive of the stage mechanism 5.

(Configuration of Irradiating Optical System)

The irradiating optical system 2 irradiates the disk medium 4 placed on a rotating stage 14 described later with an electron beam. The irradiating optical system 2 mainly includes an electron gun 7, a blanking electrode 8, a focusing lens 9, an aperture 10, a deflector 11, and an object lens 12.

The electron gun 7 is a source of an electron beam. The electron gun 7 is disposed opposite to the disk medium 4 supported by the stage mechanism 5. The electron gun 7 generates the electron beam downward.

The blanking electrode 8 controls the electron beam to travel downstream. When blanking is conducted, the blanking electrode 8 deflects an axis of the electron beam by an electric field so that the electron beam is intercepted by an aperture 10; and when blanking is not conducted, the blanking electrode 8 allows the electron beam to pass through the opening 13 of the aperture 10. The blanking electrode 8 is disposed between the electron gun 7 and the focusing lens 9 on a trajectory of the electron beam starting from the electron gun 7 to the disk medium 4.

The focusing lens 9 suppresses the expansion of the diameter of the electron beam exiting from the electron gun 7. The focusing lens 9 is disposed between the blanking electrode 8 and the aperture 10 on the trajectory of the electron beam starting from the electron gun 7 to the disk medium 4.

The aperture 10 blocks an unnecessary electron beam in order to selectively irradiate a disk medium with an electron beam when radiating the electron beam. The aperture 10 is integrated with an opening 13 that allows the electron beam to pass through. The aperture 10 is disposed between the focusing lens 9 and the deflector 11 on the trajectory of the electron beam starting from the electron gun 7 to the disk medium 4.

The deflector 11 changes a direction (traveling direction) of an electron beam that has passed through the opening 13 of the aperture 10, thereby result in changing an irradiating position of the electron beam on a disk medium. The deflector 11 is disposed between the aperture 10 and the object lens 12 on the trajectory of the electron beam starting from the electron gun 7 to the disk medium 4.

The object lens 12 narrows a diameter of an electron beam that has passed through the opening 13 of the aperture 10. The object lens 12 is disposed between the deflector 11 and the stage mechanism 5 on the trajectory of the electron beam starting from the electron gun 7 to the disk medium 4.

(Configuration of Electron Detector)

The electron detector 3 detects electrons that are generated from the disk medium 4 located on the rotating stage 14 by irradiating the disk medium 4 with an electron beam, using the irradiating optical system 2. More specifically, the electron detector 3 detects the electrons generated from a surface of the disk medium 4 (the location irradiated with the electron beam) when the disk medium 4 supported by the stage mechanism 5 is irradiated with the electron beam of the irradiating optical system 2. The electron detector 3 is disposed obliquely above the disk medium 4 supported by the stage mechanism 5. Among the electrons generated from the disk medium 4 by the irradiation of the electron beam, the electron detector 3 mainly detects secondary electrons; however, electrons to be detected actually include reflected electrons. Anyhow, an electron detection signal detected by the electron detector 3 reflects a surface state (concavo-convex state) of the disk medium 4. The electron detection signal obtained by the electron detector 3 is transmitted to the signal processing unit 18.

The signal processing unit 18 receives the detection signal transmitted from the electron detector 3 and conducts various processing operations by use of the detection signal. Specifically, the signal processing unit 18 determines, for example, whether an inspection target pattern is good or not (the detail will be described later).

(Configuration of Stage Mechanism)

The stage mechanism 5 rotates or moves the disk medium 4 while supporting the disk medium 4. The stage mechanism 5 includes a rotatable rotating stage 14 and a translatory stage 15 for linearly moving the rotating stage 14. The rotating stage 14 and the translatory stage 15 constitute an “r-θ system” stage having a function to rotate the disk medium 4 and a function to move the disk medium 4.

The rotating stage 14 horizontally supports the disk medium 4 placed thereon and also rotates the supported disk medium 4 in the circumferential direction. The rotating stage 14 rotates by means of a drive source, such as a spindle motor not shown.

The translatory stage 15 linearly travels in the uniaxial direction parallel to a horizontal plane (hereafter, simply referred to as “horizontal direction”). However, the translatory stage 15 may be configured to travel not only in the uniaxial direction but also in the orthogonal biaxial directions parallel to the horizontal plane (so-called XY directions). The translatory stage 15 travels in the horizontal direction together with the rotating stage 14 and the disk medium 4. The translatory stage 15 is a moving means for moving the disk medium 4 supported by the rotating stage 14 in the radial direction (direction of radius) of the disk medium 4.

(Stage Control System)

The stage control system 6 includes a rotating-stage control unit 16 for controlling the rotating stage 14 and a translatory-stage control unit 17 for controlling the translatory stage 15.

The rotating-stage control unit 16 controls the drive (rotation operation) of the rotating stage 14. More specifically, for example, the rotating-stage control unit 16 controls a rotation speed and a rotation direction of the rotating stage 14 in addition to the basic operations of rotation and stop of the rotating stage 14. The rotation speed of the rotating stage 14, described herein, is expressed by a number of rotation per unit time (unit: rpm). The rotating-stage control unit 16 recognizes the current position (rotation phase) in the rotation direction of the rotating stage 14 by use of, for example, a rotation position detection sensor (not shown) provided in the pattern inspection device 1.

The translatory-stage control unit 17 controls the drive (traveling operation) of the translatory stage 15. More specifically, for example, the translatory-stage control unit 17 controls a traveling speed and a traveling direction of the translatory stage 15 in addition to the basic operations of traveling and stop of the translatory stage 15. The translatory-stage control unit 17 may be configured to recognize the current position in the traveling direction of the translatory stage 15 as needed, by use of, for example, a traveling position detection sensor (not shown) provided in the pattern inspection device 1.

<2. Structure of Disk Medium>

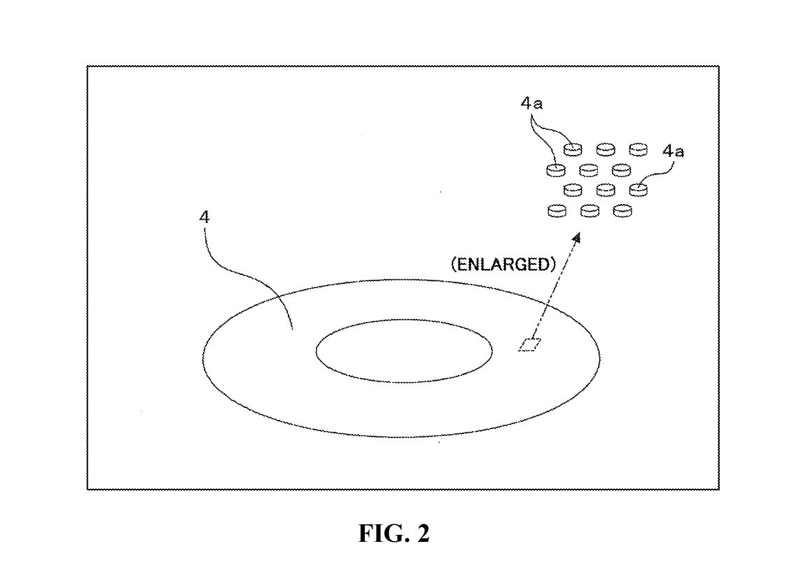

FIG. 2 shows an example of a structure of a disk medium which is a pattern inspection target.

The illustrated disk medium 4 is a disk medium for a bit patterned media, and substantially has a disk shape. On one main surface of the disk medium 4, a plurality of tracks (not shown) are concentrically formed. A pattern in each track forms a bit pattern 4a which is spaced for each bit in the radial and circumferential directions of the disk medium 4. A plurality of bit patterns 4a arranged on the circumference having the same radius around the center of the disk medium 4 constitute a track. Each bit pattern 4a is formed in a circular shape in a planar view. Furthermore, each bit pattern 4a is a convex pattern that protrudes from one main surface of the disk medium 4 in the thickness direction of the disk medium 4. Therefore, the surface (pattern-forming surface) of the disk medium 4 is formed into a concavo-convex state by the presence of the plurality of bit patterns 4a that constitute each track.

<3. Pattern Inspection Method>

Next, a pattern inspection method according to the embodiment of the present invention will be described. This pattern inspection method uses the above-mentioned pattern inspection device 1. Furthermore, in the configuration of the pattern inspection device 1, a spot diameter of the electron beam of the irradiating optical system 2 is set larger than the diameter of the bit pattern 4a of the disk medium 4. The spot diameter of the electron beam exiting from the irradiating optical system 2 can be adjusted by adjusting optical characteristics of the electron gun 7, focusing lens 9, object lens 12, etc. as the parameters.

The spot diameter of the electron beam, described herein, is defined by a spot diameter of the electron beam that is formed on a surface of the disk medium 4 by targeting the surface, when the surface (pattern-forming surface) of the disk medium 4 is irradiated with the electron beam. By contrast, provided that the bit pattern 4a is a circular shape in a planar view as described above, a pattern diameter of the bit pattern 4a is defined by the diameter of the bit pattern 4a itself.

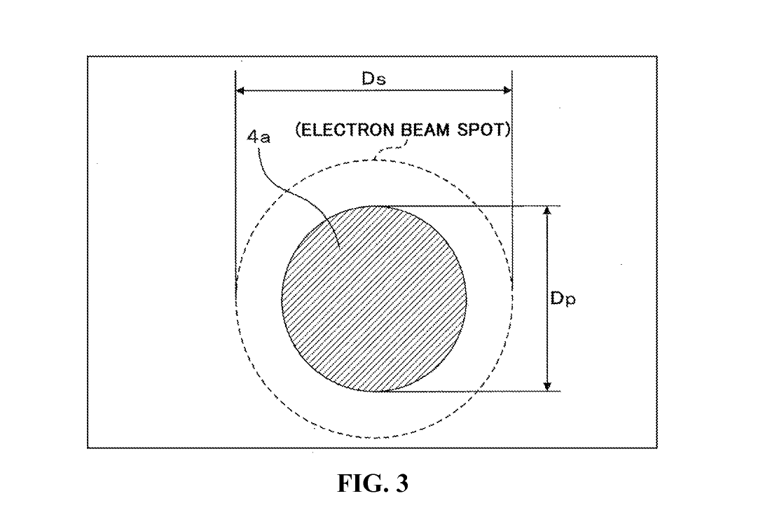

FIG. 3 is a plan view showing an example of dimensional relationship between a spot diameter of an electron beam and a bit pattern diameter. As shown in the drawing, provided that the spot diameter of the electron beam is Ds and the diameter of the bit pattern 4a is Dp, it is preferable that the relationship between those diameters be specified by taking into account the dimensional variation of the pattern diameter of the bit pattern 4a.

Hereafter, procedures of the pattern inspection method that uses the pattern inspection device 1 will be described.

First, an inspection target disk medium 4 is placed on the rotating stage 14 and fixedly supported by a mechanical chuck or the like. In this process, the disk medium 4 is horizontally disposed so that a surface on which the bit pattern 4a is formed faces up.

Next, a predetermined initialization operation (for example, operation for detecting a reference position in the rotation direction of the rotating stage 14, or operation for detecting a reference position in the traveling direction of the translatory stage 15) is conducted, as needed. Each of the reference positions is detected by use of, for example, the above-mentioned rotation position detection sensor or traveling position detection sensor.

Next, the disk medium 4 supported by the rotating stage 14 is arranged at a predetermined initial position and then rotated by means of the drive of the rotating stage 14 based on the control instruction transmitted from the rotating-stage control unit 16. When the rotation speed of the disk medium 4 is stabilized at a predetermined speed, the disk medium 4 is irradiated with an electron beam of the irradiating optical system 2. Then, a surface (main surface) of the disk medium 4 is scanned in the circumferential direction by the electron beam according to the rotation of the rotating stage 14. During this process, if the disk medium 4 is irradiated with the electron beam while the disk medium 4 is moved in the radial direction by the translatory stage 15, the electron beam will plot a spiral trajectory due to the rotation of the disk medium 4. For this reason, it is required to correct a position of the electron beam by the deflector 11 so that the electron beam plots a circle instead of a spiral.

Furthermore, when the disk medium 4 is irradiated with the electron beam of the irradiating optical system 2, an irradiation target is the bit patterns 4a of any one of plurality of tracks that are concentrically formed on the disk medium 4. Therefore, the electron beam from the irradiating optical system 2 is radiated onto a position on the circumference on which the bit patterns 4a of an inspection target track located on the disk medium 4 are formed.

Meanwhile, the electron detector 3 detects an electron (mainly a secondary electron) generated from the disk medium 4 by the irradiation of the electron beam. Furthermore, the electron detector 3 transmits a detection signal created by the detection of electron to the signal processing unit 18.

Then, the signal processing unit 18 receives the detection signal transmitted from the electron detector 3 and executes processing related to the pattern inspection, for example, under the following conditions.

(Prerequisite 1)

When the disk medium 4 is irradiated with an electron beam of the irradiating optical system 2, while aiming the bit pattern 4a constituting a certain track as an inspection target, an intensity of the detection signal obtained from the electron detector 3 changes by a “relative positional relation” between the bit pattern 4a formed on the surface of the disk medium 4 and the electron beam spot radiated thereon.

(Prerequisite 2)

When the above “relative positional relation” changes continuously (with time) according to the rotation of the disk medium 4 placed on the rotating stage 14, the intensity of the detection signal obtained from the electron detector 3 continuously changes accordingly.

(Prerequisite 3)

In the above “relative positional relation”, as the area of the bit pattern 4a that occupies a portion in the electron beam spot increases, the intensity of the detection signal obtained from the electron detector 3 increases; and on the contrary, as the area of the bit pattern 4a that occupies a portion in the electron beam spot decreases, the intensity of the detection signal obtained from the electron detector 3 decreases.

(Prerequisite 4)

As one of various types of data used for the pattern inspection, the signal processing unit 18 internally or externally stores reference signal data that is used for the comparison with the above detection signal. The internal data storage is achieved by, for example, a memory of the signal processing unit 18 itself. The external data storage is achieved by, for example, an external storage such as a hard disk drive. The reference signal data thus stored is prepared in advance in accordance with, for example, the pattern form (shape, size, etc.) of an inspection target disk medium 4, rotation speed of the rotating stage 14, and the spot diameter of the electron beam radiated from the irradiating optical system 2. Furthermore, the reference signal is specified according to a waveform (intensity profile) of the detection signal that is obtained from the electron detector 3 when the bit pattern 4a is formed as designed.

(Detailed Processing Related to Pattern Inspection)

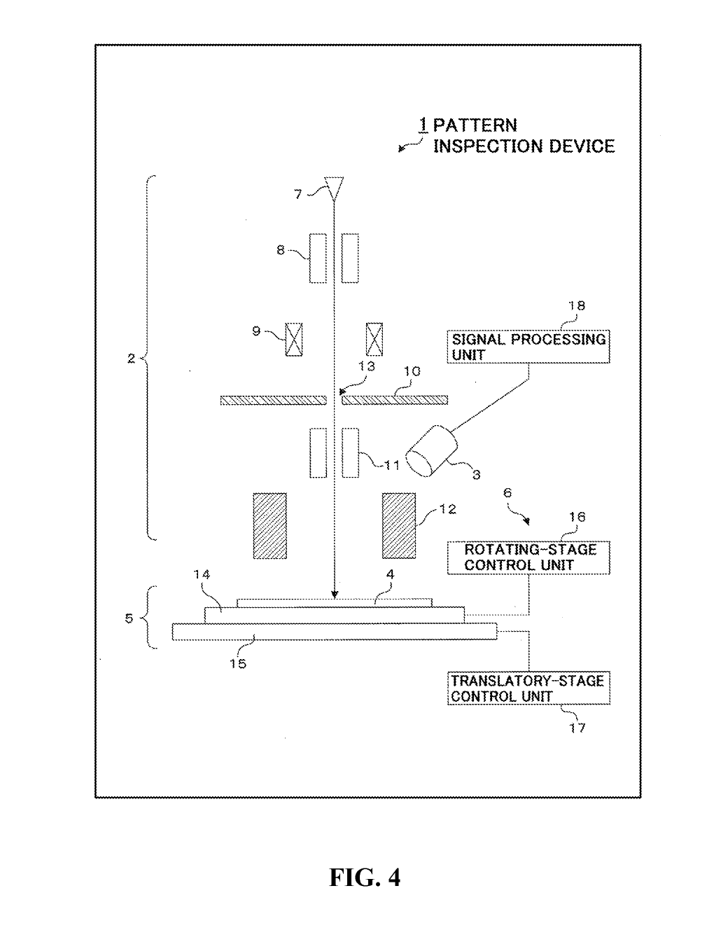

When the electron beam spot relatively travels on (scans) a portion of a certain bit pattern 4a that constitutes a certain track from one direction to the other along the circumferential direction (rotation direction) of the disk medium 4, an intensity profile of the detection signal that is obtained by detecting electrons, which are generated at the electron beam irradiation position by the electron detector 3, has a mound-like profile, as shown in FIG. 4, in accordance with the above “prerequisites 1 to 3”. In FIG. 4, the intensity profile of the signal is shown in a graph (two-dimensional coordinates) in which the signal intensity is plotted on the vertical axis and a time is plotted on the horizontal axis. Optionally, the intensity profile of the detection signal has the same shape when a rotation phase angle of the rotating stage 14 is plotted on the horizontal axis instead of the time.

When focusing attention on a certain track, a bit pattern 4a is formed on the surface of the disk medium 4 in a row for each bit in the circumferential direction of the disk medium 4. Therefore, if the electron beam irradiation position (position of the spot) is displaced in the circumferential direction of the disk medium 4 according to the rotation of the disk medium 4, a mound-like detection signal as shown in FIG. 4 can be obtained every time when the electron beam spot Bs crosses the portion of each bit pattern 4a.

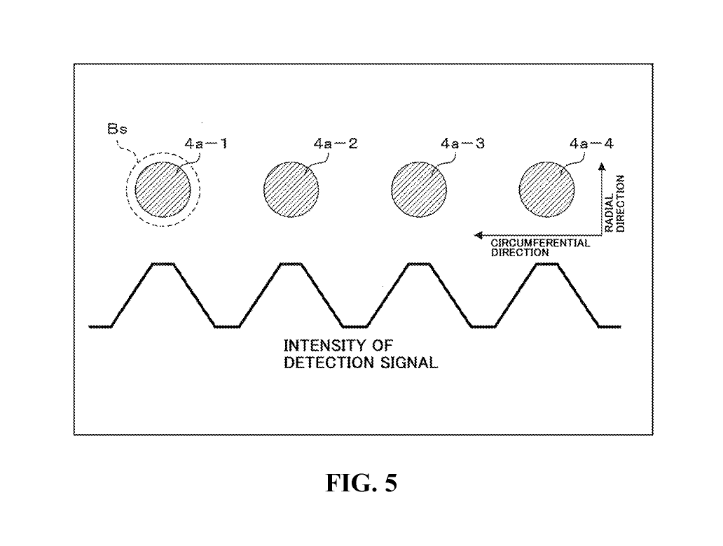

Therefore, assuming that bit patterns 4a-1, 4a-2, 4a-3, and 4a-4 that constitute a certain track are of the same shape and size and placed in a row at constant pitches (physical intervals) in the circumferential direction of the disk medium 4, as shown in the upper part of FIG. 5, under the conditions that the rotation speed of the rotating stage 14 is constant, the form of the detection signal obtained from the electron detector 3 has a shape as shown in the lower part of FIG. 5. That is, the electron detector 3 outputs detection signals having the mound-like intensity profile, which are of the same intensity and the same width, at constant pitches (temporal intervals) so that each signal corresponds to each bit pattern 4a with one-to-one correspondence.

Based on the above facts, the signal processing unit 18 determines whether the pattern is good or not by inspection as described below. Herein, the determination processing will be described in separate cases: the case where “a position of the bit pattern is misaligned in the circumferential direction of the disk medium”; the case where “a position of the bit pattern is misaligned in the radial direction of the disk medium”; and the cases where “a bit pattern diameter is different from the reference pattern diameter”.

In the case where the position of the bit pattern is misaligned in the circumferential direction of the disk medium:

When the position of the bit pattern is misaligned in the circumferential direction of the disk medium, whether the pattern is good or not is determined based on the time lag of the output timing of a detection signal caused by the misalignment of the position. Specifically, the following processing is conducted.

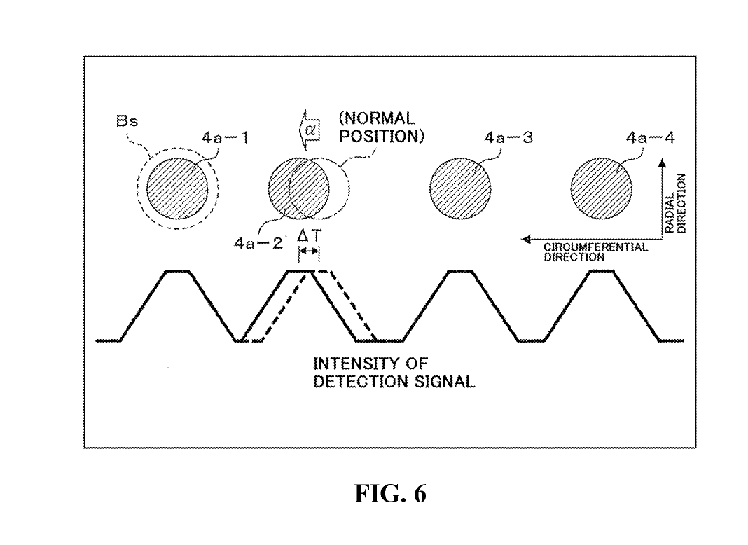

Now, as shown in the upper part of FIG. 6, the following situation is assumed: With respect to a plurality of bit patterns 4a-1, 4a-2, 4a-3, and 4a-4 placed in a row in the circumferential direction of the disk medium 4, a position of the bit pattern 4a-2 is misaligned by a from the normal reference position (position indicated by the dashed line in the drawing) in the circumferential direction of the disk medium 4. In this case, a pitch (physical interval) between the bit pattern 4a-1 and the bit pattern 4a-2 which are adjacent to each other in the circumferential direction of the disk medium 4 becomes smaller by a than the reference pitch; and accordingly, a pitch (physical interval) between the bit pattern 4a-2 and the bit pattern 4a-3 becomes larger by a than the reference pitch.

Accordingly, when the electron beam spot Bs travels to sequentially irradiate (scan) each portion of the bit patterns 4a-1, 4a-2, 4a-3, and 4a-4, a detection signal to be obtained from the electron detector 3 has a waveform as shown in the lower part of FIG. 6.

That is, a pitch (temporal interval) between the mound-like detection signal obtained when the electron beam spot Bs scans the portion of the bit pattern 4a-1 and the mound-like detection signal obtained when the portion of the bit pattern 4a-2 is scanned, becomes smaller than the reference pitch due to the positional misalignment a of the bit pattern 4a-2.

On the other hand, a pitch (temporal interval) between the mound-like detection signal obtained when the electron beam spot Bs scans the portion of the bit pattern 4a-2 and the mound-like detection signal obtained when the electron beam spot Bs scans the portion of the bit pattern 4a-3 becomes larger than the reference pitch due to the positional misalignment a of the bit pattern 4a-2.

Assuming that the bit patterns 4a-3 and 4a-4 are formed without being misaligned in the circumferential direction of the disk medium 4, the “reference pitch” described herein corresponds to the pitch (temporal interval) between the two mound-like detection signals obtained when the electron beam spot Bs scans the portions of the bit patterns 4a-3 and 4a-4.

Accordingly, the signal processing unit 18 determines whether the bit pattern 4a is good or not according to, for example, the following judgment criterion:

First, by comparing an output timing of a detection signal obtained when the electron beam spot Bs scans the portion of each bit pattern 4a with the output timing of the reference signal, a time lag between the two signals is recognized. The comparison of the output timing is made for each bit pattern 4a. Furthermore, the detection signal output timing is defined by a timing that is uniquely determined during the period when the detection signals are outputted, for example, at the center of the period when detection signals having the mound-like intensity profile are outputted. This is the same as the reference signal output timing.

Then, as shown in FIG. 6, when there is a time lag between an output timing of the detection signal obtained when the electron beam spot Bs scans the portion of the bit pattern 4a-2 and an output timing of the corresponding reference signal (indicated by the broken line in the drawing), an amount of time lag ΔT is recognized. Then, a comparison is made between the recognized amount of time lag ΔT and the predetermined allowable value Tk, and based on the comparison result, whether the bit pattern 4a-2 is good or not, that is, whether it is a good pattern or a defective pattern is determined. Specifically, when the amount of time lag ΔT exceeds the allowable value Tk, it is determined that the bit pattern 4a-2 is a defective pattern. When the amount of time lag ΔT is equal to or less than the allowable value Tk, it is determined that the bit pattern 4a-2 is a good pattern. In this case, the allowable value Tk which is used as a comparison criterion for the determination is given in advance (e.g., stored in the memory) to the signal processing unit 18 in accordance with the desired accuracy of the pattern.

In the case where a position of the bit pattern is misaligned in the radial direction of the disk medium:

When the position of the bit pattern is misaligned in the radial direction of the disk medium, whether the bit pattern is good or not is determined based on the intensity and width of the detection signal which is generated by the positional misalignment. Specifically, the following processing is conducted.

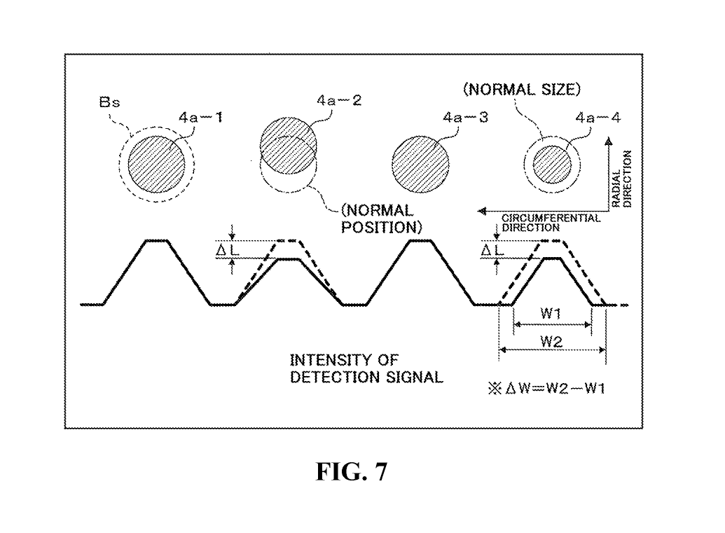

Now, as shown in the upper part of FIG. 7, the following situation is assumed: With respect to a plurality of bit patterns 4a-1, 4a-2, 4a-3, and 4a-4 placed in a row in the circumferential direction of the disk medium 4, a position of the bit pattern 4a-2 is misaligned from a normal reference position in the radial direction of the disk medium 4. In that situation, if an amount of positional misalignment of the bit pattern 4a-2 exceeds a certain level, a part of the bit pattern 4a-2 (the upper part of the bit pattern 4a-2 in the drawing) will go beyond the area to be scanned by the electron beam spot Bs.

Accordingly, when the electron beam spot Bs travels to sequentially irradiate (scan) each portion of the bit patterns 4a-1, 4a-2, 4a-3, and 4a-4, a detection signal to be obtained from the electron detector 3 has a waveform as shown in the lower part of FIG. 7.

That is, an intensity of the mound-like detection signal obtained when the portion of the bit pattern 4a-2 is scanned by the electron beam spot Bs becomes lower than the intensity of the mound-like detection signal obtained when the portion of the bit pattern 4a-1 is scanned. However, a width of the mound-like detection signal obtained when the portion of the bit pattern 4a-1 is scanned by the electron beam spot Bs is equal to the width of the mound-like detection signal obtained when the formation portion of the bit pattern 4a-2 is scanned.

Accordingly, the signal processing unit 18 determines whether the bit pattern 4a is good or not according to, for example, the following judgment criterion:

First, by comparing an intensity of detection signal obtained when a portion of each bit pattern 4a is scanned by the electron beam spot Bs with the intensity of the reference signal, an intensity difference between the two signals is recognized. This comparison is made for each bit pattern 4a.

Then, as shown in FIG. 7, when there is a difference between the intensity of the detection signal obtained when the electron beam spot Bs scans the portion of the bit pattern 4a-2 and the intensity of a corresponding reference signal (indicated by the broken line in the drawing), the intensity difference ΔL is recognized. Then, a comparison is made between the intensity difference ΔL and the predetermined allowable value Lk, and based on the comparison result, whether the bit pattern 4a-2 is good or not (good pattern or defective pattern) is determined. Specifically, when the intensity difference ΔL exceeds the allowable value Lk, it is determined that the bit pattern 4a-2 is a defective pattern. When the intensity difference ΔL is equal to or less than the allowable value Lk, it is determined that the bit pattern 4a-2 is a good pattern. In this case, the allowable value Lk which is used as a comparison criterion for the determination is given in advance to the signal processing unit 18 in accordance with the desired accuracy of the pattern.

In the case where a bit pattern diameter is different from the reference pattern diameter:

When the bit pattern diameter is different from the reference pattern diameter, whether the bit pattern is good or not is determined based on the intensity and width of the detection signal caused by the difference of the pattern diameters. Specifically, the following processing is conducted.

Now, as shown in the upper part of FIG. 7, the following situation is assumed: With respect to a plurality of bit patterns 4a-1, 4a-2, 4a-3, and 4a-4 placed in a row in the circumferential direction of the disk medium 4, a diameter of a bit pattern 4a-4 is smaller than the reference pattern diameter. In that situation, when the bit pattern 4a-4 is located at the center of the electron beam spot, an area of the bit pattern 4a-4 that occupies a portion in the spot becomes smaller than the reference area. The reference area is defined by an area of a bit pattern 4a that occupies a portion in the spot, when the bit pattern 4a that has the same pattern diameter as the reference pattern diameter is located at the center of the electron beam spot.

Accordingly, when the electron beam spot travels to sequentially irradiate (scan) each portion of the bit patterns 4a-1, 4a-2, 4a-3, and 4a-4, a detection signal obtained from the electron detector 3 has a waveform as shown in the lower part of FIG. 7.

That is, an intensity and a width of the mound-like detection signal obtained when a portion of the bit pattern 4a-4 is scanned by the electron beam spot Bs become smaller than the intensity and width of the reference signal. That is, the intensity of the mound-like detection signal obtained when the portion of the bit pattern 4a-4 is scanned by the electron beam spot Bs becomes lower by ΔL than the intensity of the reference signal (indicated by the broken line in the drawing). Furthermore, a width W1 of the mound-like detection signal obtained when the portion of the bit pattern 4a-4 is scanned by the electron beam spot Bs becomes smaller by ΔW than the width W2 of the reference signal.

Furthermore, although not shown, when the diameter of the bit pattern 4a which is an inspection target is larger than the reference pattern diameter, the intensity and width of the mound-like detection signal obtained when the portion of the bit pattern 4a is scanned by the electron beam spot become larger than the intensity and width of the reference signal.

Accordingly, the signal processing unit 18 determines whether the bit pattern 4a is good or not according to, for example, the following criterion for determination.

First, by comparing the intensity and width of the detection signal obtained when the portion of each bit pattern 4a is scanned by the electron beam spot Bs with the intensity and width of the reference signal, amounts of the relative misalignments ΔL and ΔW are recognized. Then, a comparison is made between the recognized amounts of misalignments ΔL and ΔW and the predetermined allowable values Lk and Wk, and based on the comparison result, whether the bit pattern 4a-4 is good or not (good pattern or defective pattern) is determined. Specifically, with respect to the intensity and width of the signal, when at least one of the amounts of the misalignments ΔL and ΔW exceeds the corresponding allowable value Lk or Wk, it is determined that the bit pattern 4a-4 is a defective pattern. When both amounts of the misalignments ΔL and ΔW are equal to or less than the corresponding allowable values Lk and Wk, it is determined that the bit pattern 4a-4 is a good pattern. At this time, the allowable values Lk and Wk which are used as the comparison criteria for determination are given in advance to the signal processing unit 18 in accordance with the desired accuracy of the pattern.

Thus, after an inspection of the positional misalignment and variation of size of the bit pattern 4a is completed for one track, an inspection target track is changed. A change of the track is performed, for example, by changing a direction of the electron beam by means of the deflector 11, or by displacing an electron beam irradiation position in the radial direction of the disk medium 4 by means of the drive of the translatory stage 15 based on the control command transmitted from the translatory-stage control unit 17. Subsequently, the same pattern inspection as mentioned above is performed for a bit pattern 4a (usually, a bit pattern 4a of an adjacent track) which is different from the bit pattern 4a of the track that is already inspected. Then, the same pattern inspection will be conducted for the bit pattern 4a of all tracks on the disk medium 4, or for the bit pattern 4a of a plurality of tracks that are predetermined.

<4. Effects of the Embodiments>

According to the pattern inspection device and the pattern inspection method in accordance with the embodiment of the present invention, the following advantageous effects can be obtained.

That is, when conducting a pattern inspection of the disk medium 4, it is possible to conduct the pattern inspection by directly using a detection signal obtained from the electron detector 3 without creating a secondary electron image based on the detection result of the electron detector 3, or without obtaining a shape and size of the pattern from the secondary electron image. As a result, it is possible to more easily conduct a pattern inspection of a disk medium, compared with the case where the shape and position of a pattern are obtained from a secondary electron image acquired by use of a scanning electron microscope.

Furthermore, in a pattern inspection that uses a detection signal obtained from the electron detector 3, it is possible to determine whether the bit pattern is good or not by comparing the detection signal with the reference signal with respect to the positional misalignment and variation of size of the bit pattern.

Specifically, when a detection signal is compared with the reference signal for each bit with respect to a signal intensity profile that is expressed by plotting the signal intensity on the vertical axis and a time on the horizontal axis, if a position of a bit pattern is misaligned in the circumferential direction or radial direction of the disk medium 4, or if a bit pattern diameter is different from the reference pattern diameter, it is possible to determine whether the bit pattern is good or not with respect to the positional misalignment and variation of size.

More specifically, when the detection signal output timing defined on the horizontal axis is compared with the reference signal output timing, if a position of a bit pattern is misaligned in the circumferential direction of the disk medium 4, it is possible to determine whether the bit pattern is good or not with respect to the amount of the positional misalignment.

Furthermore, when an intensity of the detection signal defined on the vertical axis is compared with the intensity of the reference signal, as well as a width of the detection signal defined on the horizontal axis is compared with the width of the reference signal, if the position of a bit pattern is misaligned in the radial direction of the disk medium 4, or if the bit pattern diameter is different from the reference pattern diameter, it is possible to determine whether the bit pattern is good or not with respect to the positional misalignment and variation of size.

<5. Modifications>

Moreover, the technical scope of the present invention is not limited to the above-mentioned embodiments, but includes a variety of modifications and alterations within the range where the specific effects can be obtained from the features of the present invention or the combination thereof.

For example, in the above embodiments, a spot diameter of the electron beam of the irradiating optical system 2 is set larger than the diameter of the bit pattern 4a, but the spot diameter of the electron beam may be set identical to the diameter of a bit pattern 4a. However, by setting the spot diameter of the electron beam larger than the diameter of the bit pattern 4a, it is possible to more specifically determine the type of the positional misalignment and variation of size of the bit pattern 4a. This is because when the spot diameter of the electron beam is set identical to the diameter of a bit pattern 4a, if the diameter of the bit pattern 4a is larger than the reference pattern diameter, the difference of the two pattern diameters is not reflected to the intensity of the detection signal. On the other hand, when the spot diameter of the electron beam is set larger than the diameter of the bit pattern 4a, the above-mentioned difference of the two pattern diameters is reflected to the intensity of the detection signal, enabling the evaluation of the bit pattern 4a.

Furthermore, a planar shape of a bit pattern of a disk medium, which is an inspection target in the present invention, is not limited to a circle as mentioned above, but may be a polygon such as a quadrangle, or an ellipse.

### REFERENCE LIST

1 Pattern inspection device
2 Irradiating optical system
3 Electron detector
4 Disk medium
4a Bit pattern
5 Stage mechanism
11 Deflector
13 Optical-system control unit
14 Rotating stage
16 Rotating-stage control unit
17 Translatory-stage control unit
18 Signal processing unit

1. A pattern inspection device for inspecting a bit pattern of a disk medium having a plurality of tracks which are concentrically formed on the disk medium, the bit pattern on each track being spaced for each bit in radial and circumferential directions, the pattern inspection device comprising:
a rotating stage on which the disk medium is placed;
an irradiating optical system for radiating an electron beam onto the disk medium that rotates together with the rotating stage; and
an electron detector for detecting electrons generated from the disk medium on the rotating stage by the irradiation of the electron beam of the irradiating optical system,
wherein a spot diameter of the electron beam of the irradiating optical system is set not less than a diameter of the bit pattern.

2. The pattern inspection device according to claim 1, further comprising:
determination means for determining whether the bit pattern is good or not by comparing a detection signal obtained for each bit as a result of detection by the electron detector with a predetermined reference signal.

3. The pattern inspection device according to claim 2,
wherein the determination means compares the detection signal with the reference signal, with respect to a signal intensity profile that is expressed by plotting the signal intensity on a vertical axis and a time on a horizontal axis.

4. The pattern inspection device according to claim 3,
wherein the determination means determines whether the bit pattern is good or not by comparing an output timing of the detection signal defined on the horizontal axis with an output timing of the reference signal.

5. The pattern inspection device according to claim 3 or 4,
wherein the determination means determines whether the bit pattern is good or not by comparing the intensity of the detection signal defined on the vertical axis with the intensity of the reference signal as well as comparing a width of the detection signal defined on the horizontal axis with a width of the reference signal.

6. A pattern inspection method for inspecting a bit pattern of a disk medium having a plurality of tracks which are concentrically formed on the disk medium, the bit pattern on each track being spaced for each bit in radial and circumferential directions, the method comprising steps of:
rotating the disk medium;
irradiating the disk medium being rotated with an electron beam;
detecting electrons generated from the disk medium at an irradiation portion of the electron beam;
setting a spot diameter of the electron beam not less than a diameter of the bit pattern; and
inspecting a bit pattern of each track.
